(19) United States
(12) Patent Application Publication
(10) Pub. No.: US 2025/0308562 A1
(43) Pub. Date: Oct. 2, 2025

(54) MITIGATING DEFORMITIES IN MEMORY ARRAYS

(71) Applicant: Micron Technology, Inc., Boise, ID (US)

(72) Inventors: Martina Damayanti, Singapore (SG); Pranav Sairam Kalaga, Singapore (SG)

(21) Appl. No.: 19/080,631

(22) Filed: Mar. 14, 2025

Related U.S. Application Data
(60) Provisional application No. 63/572,056, filed on Mar. 29, 2024.

(51) Int. Cl. G11C 5/06; G11C 16/04; H10B 41/10; H10B 41/27; H10B 41/35; H10B 43/10; H10B 43/27; H10B 43/35

(52) U.S. Cl. CPC G11C 5/063; G11C 16/0483; H10B 41/10; H10B 41/27; H10B 41/35; H10B 43/10; H10B 43/27; H10B 43/35

(57) ABSTRACT

Methods, systems, and devices for mitigating deformities in memory arrays are described. A stack of materials may be formed into a memory array. For example, the stack may include a set of oxide and nitride layers and has an array portion, a staircase portion, and a boundary portion between the array portion and the staircase portion. In one example, a respective slit may be etched across a subset of the boundary portion and across one or more conductive pillars formed in the staircase portion. After etching such slits, dielectric material may be deposited into each of the slits, thereby reinforcing the boundary portion. In another example, a first quantity of layers at a first portion of the array portion may be removed and replaced by oxide, such that a distance between the first quantity of layers at the array portion and the set of conductive pillars may be increased.

### CROSS REFERENCE

The present Application for Patent claims priority to U.S. Patent Application No. 63/572,056 by Damayanti et al., entitled “MITIGATING DEFORMITIES IN MEMORY ARRAYS,” filed Mar. 29, 2024, which is assigned to the assignee hereof, and which is expressly incorporated by reference in its entirety herein.

### TECHNICAL FIELD

The following relates to one or more systems for memory, including mitigating deformities in memory arrays.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a system that supports mitigating deformities in memory arrays in accordance with examples as disclosed herein.

FIG. 2A shows an example of a memory array that supports mitigating deformities in memory arrays in accordance with examples as disclosed herein.

FIG. 2B shows an example of a memory array that supports mitigating deformities in memory arrays in accordance with examples as disclosed herein.

FIG. 3A shows an example of a processing step that supports mitigating

deformities in memory arrays in accordance with examples as disclosed herein.

FIG. 3B shows an example of a processing step that supports mitigating deformities in memory arrays in accordance with examples as disclosed herein.

FIG. 4A shows an example of a processing step that supports mitigating deformities in memory arrays in accordance with examples as disclosed herein.

FIG. 4B A shows an example of a processing step that supports mitigating deformities in memory arrays in accordance with examples as disclosed herein.

FIG. 5A shows an example of a processing step that supports mitigating deformities in memory arrays in accordance with examples as disclosed herein.

FIG. 5B shows an example of a processing step that supports mitigating deformities in memory arrays in accordance with examples as disclosed herein.

FIG. 6A shows an example of a processing step that supports mitigating deformities in memory arrays in accordance with examples as disclosed herein.

FIG. 6B shows an example of a processing step that supports mitigating deformities in memory arrays in accordance with examples as disclosed herein.

FIG. 7A shows an example of a processing step that supports mitigating deformities in memory arrays in accordance with examples as disclosed herein.

FIG. 7B shows an example of a processing step that supports mitigating deformities in memory arrays in accordance with examples as disclosed herein.

FIGS. 8 and 9 show flowcharts illustrating a method or methods that support mitigating deformities in memory arrays in accordance with examples as disclosed herein.

### DETAILED DESCRIPTION

Some memory arrays (e.g., not-and (NAND) arrays) may be manufactured using a process that includes forming a stack of materials, where the stack of materials may have an array portion, a staircase portion, and a boundary portion between the array portion and the staircase portion. The stack of materials may include alternating oxide and nitride layers (e.g., levels). Based on forming the stack of the materials, a metallization procedure (e.g., replacement gate procedure) may be performed, where, during the metallization procedure, the nitride layers may be removed to form a set of cavities (in place of the vacated nitride layers) and subsequently metal may be deposited into the set of cavities to form a set of word lines. The set of word lines may span both the array portion and staircase portion of the stack of materials.

In response to forming the word lines, a set of conductive pillars may be formed at the staircase portion of the stack, where each conductive pillar may be configured to couple with a respective word line of the stack. For example, a first conductive pillar may be configured to couple with a first word line of the stack, while a second conductive pillar may be configured to couple with a second word line of the stack, and so on. Additionally, prior to, or after, forming the set of conductive pillars, a set of memory cells may be formed at each word line of the array portion of the stack and be configured to couple with a respective word line of the set of word lines. Such sets of memory cells may be referred to as a memory block. After forming the memory block at the array portion and the set of conductive pillars at the staircase portion, a set of slits (e.g., trenches) may be etched across the array portion and the staircase portion of the stack, thereby separating the memory block into one or more subblocks. After etching the set of slits, a dielectric material may be deposited into the slits, thereby forming a set of insulating walls.

In such manufacturing processes, however, cracks (e.g., fractures) may be formed at the boundary portion between the memory subblocks (e.g., the start of the array portion) and a first subset of the set of conductive pillars (e.g., the conductive pillars closest to the memory subblocks, the start of the staircase portion) due to stress. Accordingly, in subsequent steps of the manufacturing process, metal may be deposited into the cracks, causing various shorts between the memory subblocks and the first subset of the set of conductive pillars. Such shorts between the memory subblocks and the first subset of the set of conductive pillars may render the memory subblocks inaccessible, reduce the lifespan of the memory device, or both, leading to failures at the memory device.

In some implementations of the present disclosure, one or more second slits may be etched across a subset of the boundary portion and across the first subset of the set of conductive pillars. Accordingly, dielectric material (e.g., oxide) may be deposited into the additional slits across the boundary portion and the first subset of the set of conductive pillars forming a second set of insulating walls. By forming the second set of insulating walls across the subset of the boundary portion and the first subset of the set of conductive pillars, such that cracks may be removed or reduced and electrical shorts caused by such cracks may be eliminated or mitigated, among other advantages.

In some other implementations of the present disclosure, a distance between a first quantity of layers at the array portion of the stack and the first subset of the set of conductive pillars may be increased, such that the stress observed at the boundary portion between the array portion and the staircase portion may be mitigated. For example, prior to performing the metallization procedure, a first quantity of layers from the staircase portion of the stack and a first portion of the array portion of the stack may be removed, thereby forming a void. Subsequently, oxide may be deposited into the void. Because the first quantity of layers from the first portion of the array portion were removed and oxide was subsequently deposited in the void, a first distance between the first subset of the set of conductive pillars in the staircase portion and the first quantity of layers of the array portion may be greater than a second distance between the set of conductive pillars and a second quantity of layers of the array portion, where the second quantity of layers of the array portion are positioned below the first quantity of layers. In this way, the stress observed at the boundary portion between the array portion and the staircase portion may be reduced, or otherwise eliminated, due to the additional oxide between the first quantity of layers and the first subset of the set of conductive pillars.

In addition to applicability in memory systems as described herein, techniques for mitigating deformities in memory arrays may be generally implemented to improve the sustainability of various electronic devices and systems. As the use of electronic devices has become even more widespread, the quantity of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing the likelihood of cracks forming between blocks of memory and one or more conductive pillars, which may extend the life of electronic devices and thereby reducing electronic waste, among other benefits.

Features of the disclosure are illustrated and described in the context of systems, devices, and circuits. Features of the disclosure are further illustrated and described in the context of memory arrays and flowcharts.

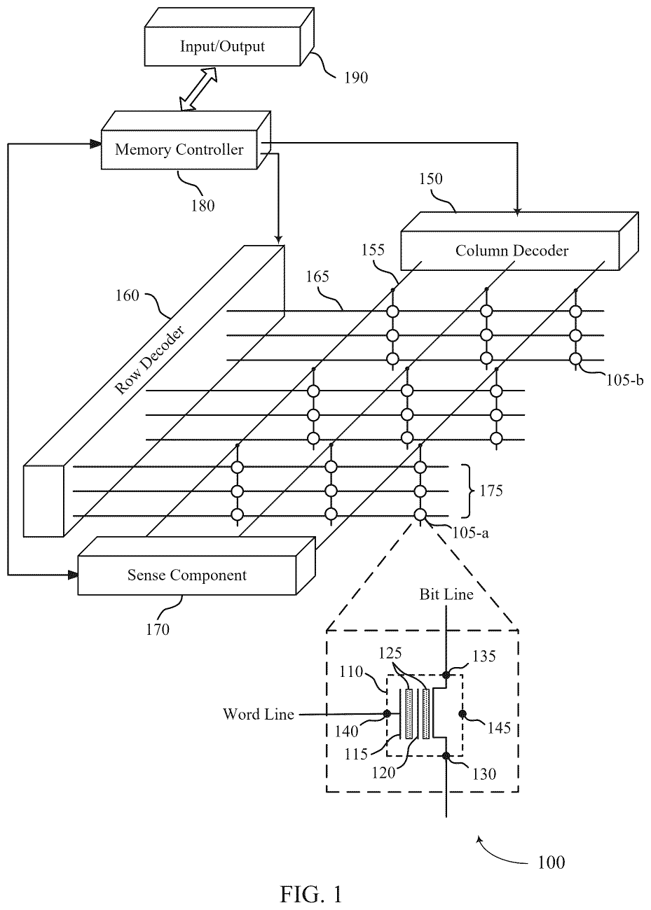

FIG. 1 shows an example of a memory device 100 that supports mitigating deformities in memory arrays in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

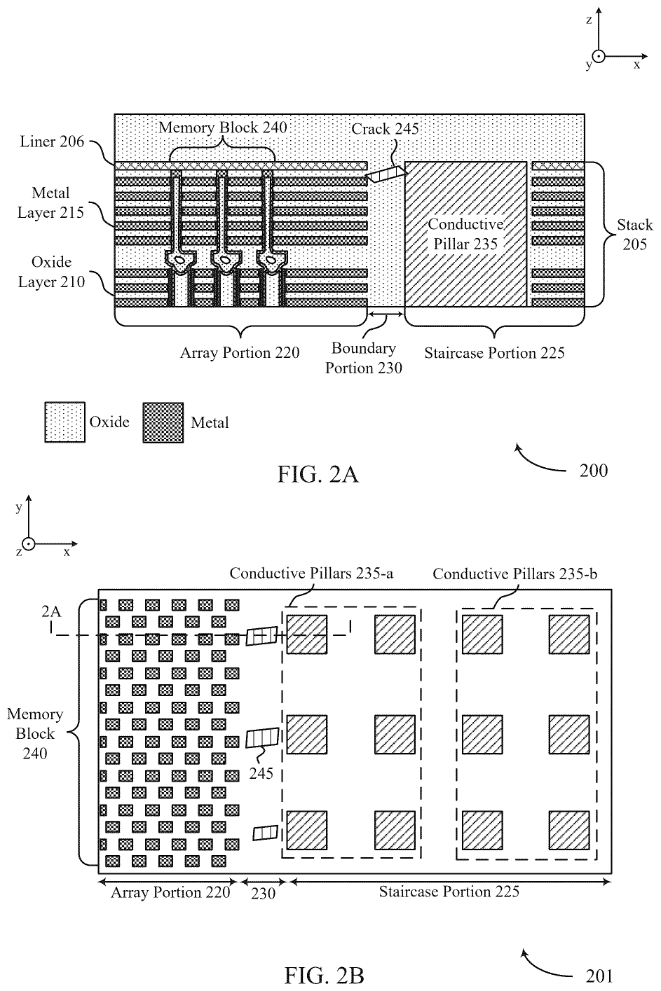

In some cases, a memory device 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

In some manufacturing processes of the memory device 100, cracks (e.g., fractures) may be formed at a boundary portion between the stack 175 and an associated conductive pillar coupled with a word line 165 due to stress. Accordingly, in subsequent steps of the manufacturing process, metal may be deposited into the cracks, causing various shorts between the stack 175 and the associated conductive pillar. Such shorts may render the stack 175 inaccessible, reduce the lifespan of the memory device 100, or both, leading to failures at the memory device 100.

In some implementations, to reduce the likelihood of cracks, a respective slit (e.g., trench) may be etched across the boundary portion between the stack 175 and the conductive pillar and across the conductive pillar itself. After etching such slits, dielectric material (e.g., oxide) may be deposited into the slit, thereby reinforcing the boundary portion, and reducing the likelihood of cracks.

FIG. 2A and 2B show examples of a memory array 200 and a memory array 201, respectively, that support mitigating deformities in memory arrays in accordance with examples as disclosed herein. The memory array 200 may be a cross sectional view (e.g., viewed according to the z axis in the vertical direction, the x axis in the horizontal direction, and the y axis going into the page) of the memory array 201. The memory array 201 may be a top view (e.g., viewed with the y axis in the vertical direction, the x axis in the horizontal direction, and the z axis going into the page) of the memory array 200.

To form the memory array 200, a stack 205 (e.g., stack of materials) may be formed with alternating material layers. For example, a first nitride layer (not shown) may be deposited over a substrate (not shown), a first oxide layer 210 may be deposited over the first nitride layer, and a second nitride layer (not shown) may be deposited over the first oxide layer 210, and so on. Accordingly, the stack 205 may be first formed by depositing alternating nitride layers and oxide layers 210. As such, the stack 205 may include a set of oxide layers 210 and a set of nitride layers (not shown). In some examples, the stack 205 may include a liner 206 deposited over a top oxide layer 210. In some examples, the stack 205 may include up to a plurality of oxide and nitride layers (e.g., 176 layer NAND). As described herein, the stack 205 may include an array portion 220, a staircase portion 225, and a boundary portion 230 between the array portion 220 and the staircase portion 225.

Based on forming the stack 205, a metallization procedure (e.g., replacement gate procedure) may be performed, where, during the metallization procedure, the nitride layers (not shown) of the stack 205 may be removed to form a set of cavities (in place of the vacated nitride layers) and subsequently metal may be deposited into the set of cavities to form a set of metal layers 215, where a metal layer 215 may be referred to as a word line 165. Such metal layers 215 may span the entirety of the array portion 220 and the staircase portion 225 in the x direction.

In response to performing the metallization procedure, a set of conductive pillars 235 may be formed at the staircase portion 225 of the stack 205. For example, a set of cavities may be formed at the staircase portion 225, where the depth of each cavity may correspond to a respective metal layer 215. That is, a first cavity may be formed, where the depth of the first cavity corresponds to a bottom metal layer 215 of the stack 205, while a second cavity may be formed where the depth of the second cavity corresponds to an intermediate metal layer 215. In this way, each cavity may be associated with a respective metal layer 215.

Based on forming the set of cavities, a conductive material may be deposited into each of the set of cavities, thereby forming the set of conductive pillars 235. With reference to the memory array 201, the conductive pillars 235-a (e.g., the first subset of the set of conductive pillars) may be referred to as support pillars (e.g., dummy contacts), while the conductive pillars 235-b (e.g., the second subset of the set of conductive pillars) may be configured to couple a respective metal layer 215 with supporting circuitry (e.g., a word line driver or row decoder 160). Additionally, with reference to the memory array 200, prior to, or after, forming the set of conductive pillars 235, a memory block 240 may be formed at the array portion 220, where the memory block 240 may include a set of memory cells that are configured to be coupled with each metal layer 215.

In such manufacturing processes, however, cracks 245 (e.g., fractures) may be formed at the boundary portion 230 between the memory block 240 (e.g., the start of the array portion) and the conductive pillars 235-a due to stress. Accordingly, in subsequent steps of the manufacturing process, metal may be deposited into the cracks 245, causing various shorts between the memory block 240 and the conductive pillars 235-a. Such shorts between the memory block 240 and the conductive pillars 235-a may render the memory block 240 inaccessible, reduce the lifespan of the memory array 200, or both, leading to failures at the memory array 200.

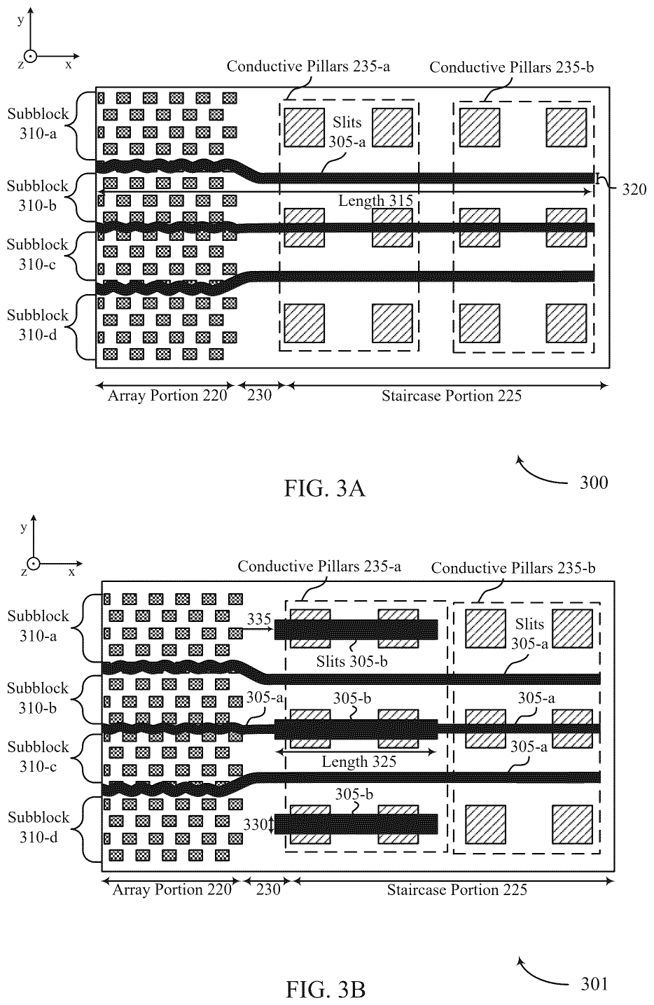

In some implementations, to reduce the likelihood of cracks 245 forming at the boundary portion 230, a respective slit (e.g., trench) may be etched across a subset of the boundary portion 230 and across each of the conductive pillars 235-a in the x direction. After etching such slits, dielectric material (e.g., oxide) may be deposited into each of the slits, thereby reinforcing the boundary portion 230. In effect, the slits are configured to remove the conductive material that filled in the cracks, and the oxide material is configured to fill the space formerly occupied by the crack 245 and its associated conductive material. Such manufacturing processes may be further described herein with respect to FIGS. 3A and 3B.

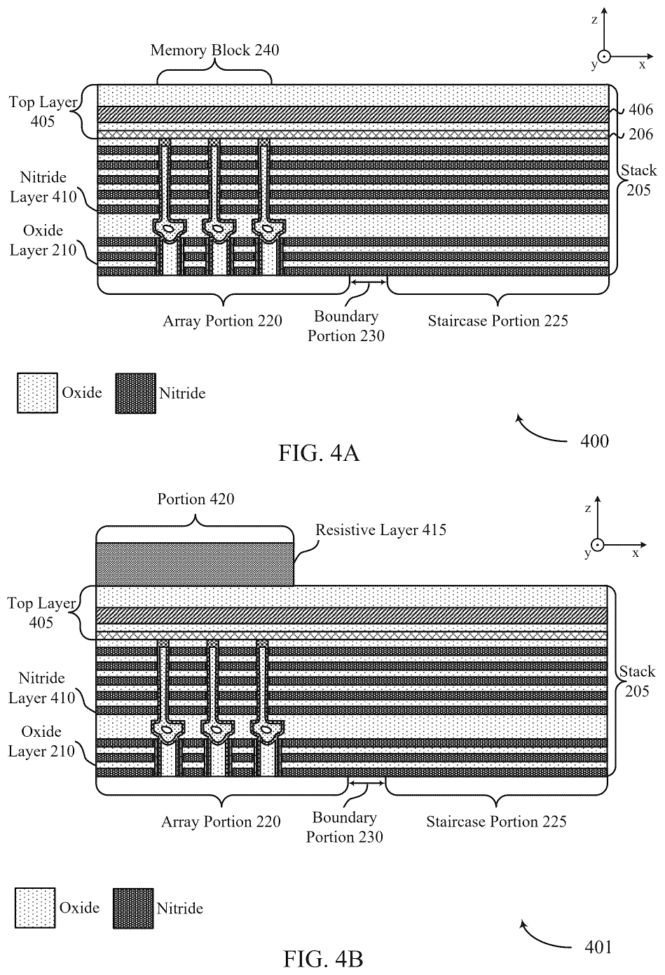

In some other implementations, prior to performing the metallization procedure, a first quantity of layers at a first portion of the array portion 220 may be removed and replaced by oxide, such that a distance between the first quantity of layers at the array portion 220 of the stack 205 and the conductive pillar 235 may be increased. In this way, the stress observed at the boundary portion 230 may be mitigated. In some examples, the increased distance may not prevent cracks 245 from forming. Instead, the increased distance may reduce a likelihood that the crack 245 stretches all the way from the array portion 220 to the conductive pillar 235. Such actions may also reduce a likelihood that an electrical short occurs between the array portion 220 and the conductive pillar 235 due to conductive material filling the crack 245. Such manufacturing processes may be further described herein with respect to FIGS. 4A-7A.

FIG. 3A shows an example of a processing step 300 that supports mitigating deformities in memory arrays in accordance with examples as disclosed herein. The processing step 300 may occur subsequent to forming the memory array 200, as described herein with reference to FIG. 2A.

Subsequent to forming the memory block 240 at the array portion 220 and the set of conductive pillars 235 at the staircase portion 225, a set of slits 305-a (e.g., first set of slits) may be etched across the array portion 220 and the staircase portion 225 of the stack 205, thereby separating the memory block 240 into one or more subblocks 310 (e.g., a subblock 310-a, a subblock 310-b, a subblock 310-c, and a subblock 310-d).

For example, a length 315 (e.g., a first length in the x direction) of the slits 305-a , a width 320 (e.g., a first width in the y direction) of the slits 305-a, and a depth (e.g., first quantity of layers in the z direction) of the slits 305-a may be identified. As described herein, a depth of a slit may correspond to a quantity of layers etched into, or removed from, the stack 205. As an illustrative example, a slit may be etched into 3 layers of the stack 205, into 5 layers of the stack 205, or, more generally, into a quantity of layers of the stack 205. The slits 305-a may be formed according to the identified length 315, width 320, and depth.

FIG. 3B shows an example of a processing step 301 that supports mitigating deformities in memory arrays in accordance with examples as disclosed herein. The processing step 301 may occur simultaneously with the processing step 301. That is, the processing step 300 and the processing step 301 may be performed in a same procedure (e.g., same etching procedure). For example, while the slits 305-a and the slits 305-b are described as being separate slits, the slits 305-a and the slits 305-b may be formed at a same time during a same manufacturing process. Accordingly, the slits 305-a and the slits 305-b may be formed as part of a same procedure, for example, during a same etching procedure.

Concurrently with etching the set of slits 305-a, slits 305-b (e.g., second set of slits) may be etched into a subset of the boundary portion 230 and across the conductive pillars 235-a. For example, a length 325 (e.g., a second length in the x direction) of the slits 305-b, a width 330 (e.g., a second width in the y direction) of the slits 305-b, and a depth (e.g., second quantity of layers in the z direction) may be identified. In such examples, the length 315 of the slits 305-a may be greater than the length 325 of the slits 305-b. In some examples, the width 320 of the slits 305-a may be greater than the width 330 of the slits 305-b, be equal to the width 330 of the slits 305-b, or be less than the width 330 of the slits 305-b. Further, the depth of the slits 305-a may be equal to the depth of the slits 305-a, may be less than the depth of the slits 305-b, or may be equal to the depth of the slits 305-b . Further, a starting point 335 of the slits 305-b within the boundary portion 230 may be identified. Accordingly, the slits 305-b may be formed according to the identified length 325, width 330, and depth, where the etching of the slits 305-b begins at the starting point 335.

After etching the slits 305-a and the slits 305-b, a dielectric material (e.g., oxide) may be deposited into the slits 305-a and the slits 305-b, thereby forming a first set of insulating walls (the oxide filled slits 305-a) and a second set of insulating walls (the oxide filled slits 305-b), respectively. By forming the second set of insulating walls across the subset of the boundary portion 230 and the conductive pillars 235-a, the boundary portion 230 may be strengthened, such that the stress (e.g., combined forces at that position of the memory array) may not cause the cracks 245 and sensitivity to such stresses may be eliminated, among other advantages.

FIG. 4A shows an example of a processing step 400 that supports mitigating deformities in memory arrays in accordance with examples as disclosed herein. The processing step 400 may occur prior to the formed memory array 200 and memory array 201, as described herein with reference to FIGS. 2A and 2B.

For example, the stack 205 may be formed with alternating oxide layers 210 and nitride layers 410, as described herein with reference to FIGS. 2A and 2B. As an illustrative example, a first nitride layer 410 may be deposited over a substrate, a first oxide layer 210 may be deposited over the first nitride layer 410, and a second nitride layer 410 may be deposited over the first oxide layer 210, and so on. In such examples, the stack 205 may include 176 alternating oxide layers 210 and nitride layers 410. As described herein, the stack 205 may have the array portion 220, the staircase portion 225, and the boundary portion 230.

A top layer 405 may be formed over a top oxide layer 210 of the alternating layers of the stack 205. In such examples, the top layer 405 may include the liner 206 deposited over the top oxide layer 210, another oxide layer 210 deposited over the liner 206, a sacrificial poly layer 406 deposited over the oxide layer 210, and a top oxide layer 210 deposited over the sac poly layer 406. In some examples, while forming the stack 205, a memory block 240 may be formed at the array portion 220 of the stack 205 as described herein with reference to FIGS. 2A and 2B.

FIG. 4B shows an example of a processing step 401 that supports mitigating deformities in memory arrays in accordance with examples as disclosed herein. The processing step 401 may follow (e.g., be subsequent to) the processing step 400. In the processing step 401, a resistive layer 415 (e.g., first resistive layer) may be deposited over a portion 420 (e.g., a second portion) of the array portion 220 of the stack 205. The resistive layer 415 may be a resistive material that prevents, or guards against, etching during an etching procedure. In some examples, a length of the resistive layer 415 (e.g., the length of the portion 420) may be identified prior to depositing the resistive layer 415. In such examples, the length of the resistive layer 415 may be identified such that a distance between a conductive pillar 235 (not shown) and a first quantity of layers of the stack 205 is increased.

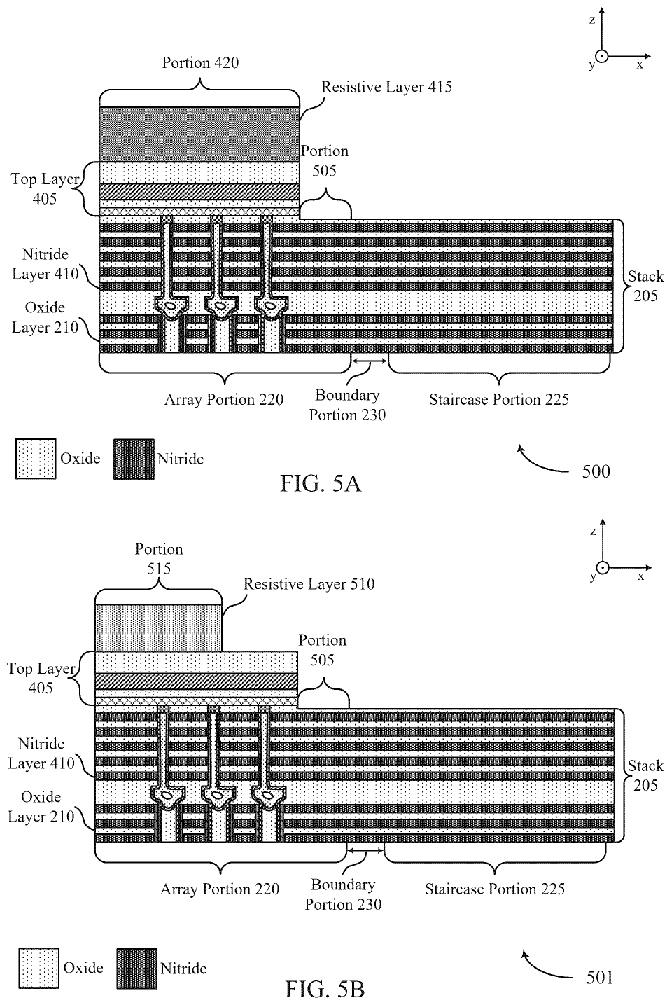

FIG. 5A shows an example of a processing step 500 that supports mitigating deformities in memory arrays in accordance with examples as disclosed herein. The processing step 500 may follow the processing step 401. That is, the processing step 500 may be performed in response to the processing step 401 being completed. For example, in response to depositing the resistive layer 415 at the processing step 401, the top layer 405 from the staircase portion 225, the boundary portion 230, and a portion 505 (e.g., first portion) of the array portion 220 may be removed. The top layer 405 over such portions of the stack 205 may be removed according to a chemical-mechanical planarization (CMP) procedure, a dry etching procedure, or a wet etching procedure. The resistive layer 415 over the portion 420 may prevent the top layer 405 of the portion 420 of the array portion 220 from being removed. Accordingly, in response to completion of the processing step 401, the resistive layer 415 may be removed from the stack 205.

FIG. 5B shows an example of a processing step 501 that supports mitigating deformities in memory arrays in accordance with examples as disclosed herein. The processing step 501 may follow the processing step 500. That is, the processing step 501 may be performed in response to the processing step 500 being completed. For example, in response to removing the resistive layer 415 from the stack 205, a resistive layer 510 (e.g., a second resistive layer) may be deposited over the top layer 405 of a portion 515 (e.g., a third portion) of the array portion 220 of the stack 205. Alternatively, a first portion of the resistive layer 41 may be removed (not shown) and another portion 515 of the resistive layer 415 may be left. In such examples, the resistive layer 510 may be an example of a portion of the resistive layer 415. The resistive layer 510 may have a same resistive material as the resistive layer 415 or be a different resistive materials as the resistive layer 415.

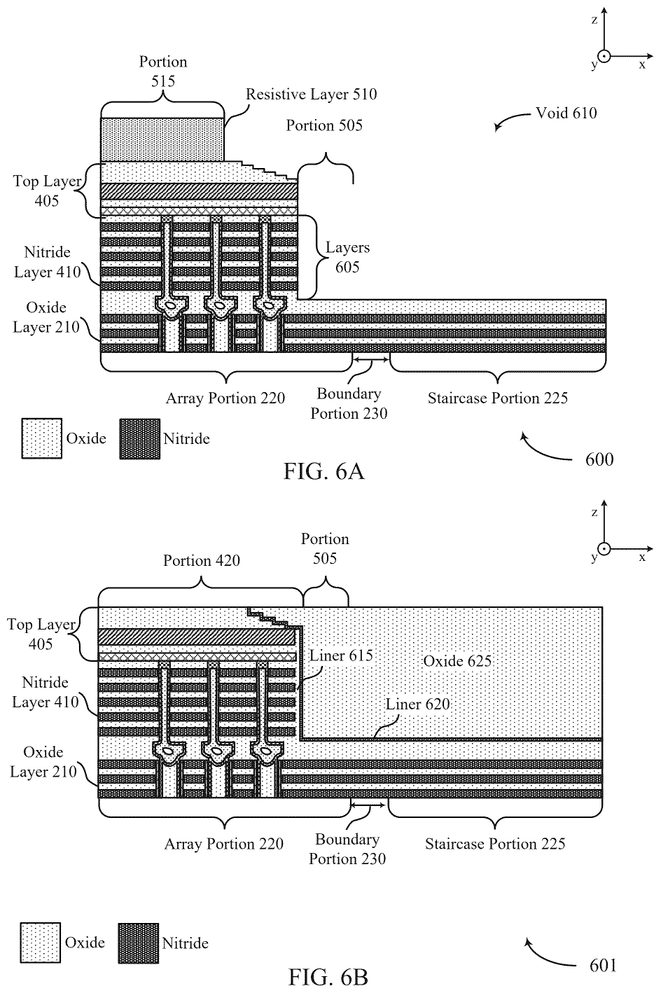

FIG. 6A shows an example of a processing step 600 that supports mitigating deformities in memory arrays in accordance with examples as disclosed herein. The processing step 600 may follow the processing step 501. That is, the processing step 600 may be performed in response to the completion of the processing step 501. For example, layers 605 (e.g., first quantity of layers) from the portion 505 of the array portion 220, the boundary portion 230, and the staircase portion 225 may be removed (e.g., exhumed) using a wet etching procedure or a dry etching procedure to form a void 610. In such examples, prior to removing the layers 605, a depth of the layers 605 (e.g., a quantity of the layers 605) may be determined. In some examples, it may be determined to remove a relatively smaller quantity of layers 605, such as up to 5 layers 605. Alternatively, it may be determined to remove a relatively larger quantity of layers 605, such as up to 10 layers 605 from the stack 205. During the processing step 600, an edge of the top oxide layer of the top layer 405 may be patterned during the removal of the layers 605 from the portion 505 of the array portion 220, from the boundary portion 230, and from the staircase portion 225. Such patterning may be formed when a dry etching procedure is used to remove the layers 605.

FIG. 6B shows an example of a processing step 601 that supports mitigating deformities in memory arrays in accordance with examples as disclosed herein. The processing step 601 may follow the processing step 600. That is, the processing step 601 may be performed in response to the completion of the processing step 600. For example, in response to removing the layers 605 from the portion 505 of the array portion 220, from the boundary portion 230, and from the staircase portion 225, the resistive layer 510 over the portion 515 of the array portion 220 may be removed. Subsequently, an oxide liner 620 may be deposited into the void 610. A liner 620 (e.g., a nitride liner) may be deposited over the oxide liner 620 and over the patterned edge of the top oxide layer 210 of the top layer 405 of the stack 205. In response to depositing the liner 620, oxide 625 may be deposited into the void 615.

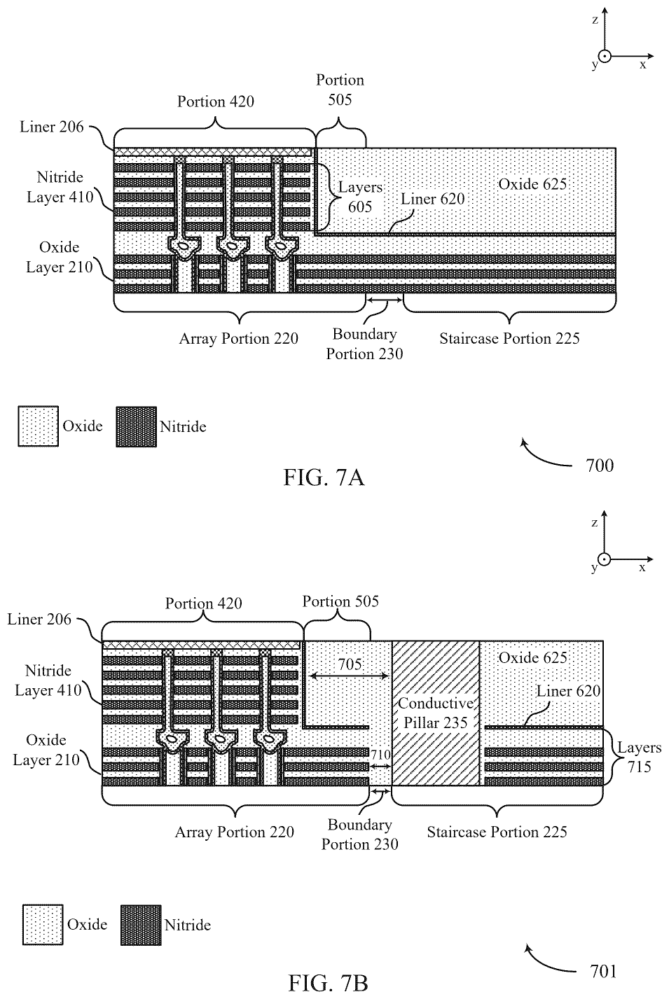

FIG. 7A shows an example of a processing step 700 that supports mitigating deformities in memory arrays in accordance with examples as disclosed herein. The processing step 700 may follow the processing step 601. That is, the processing step 700 may be performed in response to completion of the processing step 601 or in conjunction with the processing step 601. For example, based on depositing the oxide liner 620, the liner 620, and the oxide 625 into the void 615, the top layer 405 of the portion 420 of the array portion 220 may be removed. In some examples, the liner 206 may not be removed during the processing step 700.

FIG. 7B shows an example of a processing step 701 that supports mitigating deformities in memory arrays in accordance with examples as disclosed herein. The processing step 701 may follow the processing step 700. That is, the processing step 701 may be performed in response to completion of the processing step 700 or in conjunction with the processing step 700.

A set of conductive pillars 235 may be formed at the staircase portion 225 of the stack 205 according to the techniques described herein with reference to FIGS. 2A and 2B. For example, a set of cavities may be formed in the oxide 625 and in layers 715 (e.g., second quantity of layers) of the stack 205. Accordingly, the set of cavities may be filled with conductive material to form the set of conductive pillars 235. The conductive pillar 235 illustrated in the processing step 701 may be part of the conductive pillars 235-a, as described herein with reference to FIG. 2B.

Accordingly, because the layers 605 of the portion 505 of the array portion 220 of the stack 205 were removed, a distance 705 (e.g., first distance) from the layers 605 and the conductive pillar 235 may be greater than a distance 710 (e.g., second distance) between the layers 715 and the conductive pillar 235. As such, because the space between the conductive pillar 235 and the layers 605 of the array portion 220 is filled with oxide 625, the stress observed at the boundary portion 230 and the staircase portion 225 may be reduced, or otherwise eliminated, due to the additional oxide 625 between the layers 605 and the conductive pillars 235. Further, if a crack 245 does form at the boundary portion 230, the likelihood of the crack extending the distance 705 to the layers 605 is relatively low, thereby protecting against shorts being formed between the layers 605 and the conductive pillar 235. That is, in some examples, the increased distance 705 may not prevent cracks 245 from forming. Instead, the increased distance 705 may reduce a likelihood that the crack 245 stretches all the way from the array portion 220 to the conductive pillar 235. Such actions may also reduce a likelihood that an electrical short occurs between the array portion 220 and the conductive pillar 235 due to conductive material filling the crack 245.

In some examples, prior to, or after forming the conductive pillar 235, a metallization procedure may be performed (e.g., a replacement gate procedure), where, during the metallization procedure, the nitride layers 410 may be removed to form a set of cavities. Subsequently, a metal may be deposited into the cavities to form metal layers 215 (e.g., word lines 165), which may be configured to couple the conductive pillar with supporting circuitry (e.g., word line drivers, among other circuitry).

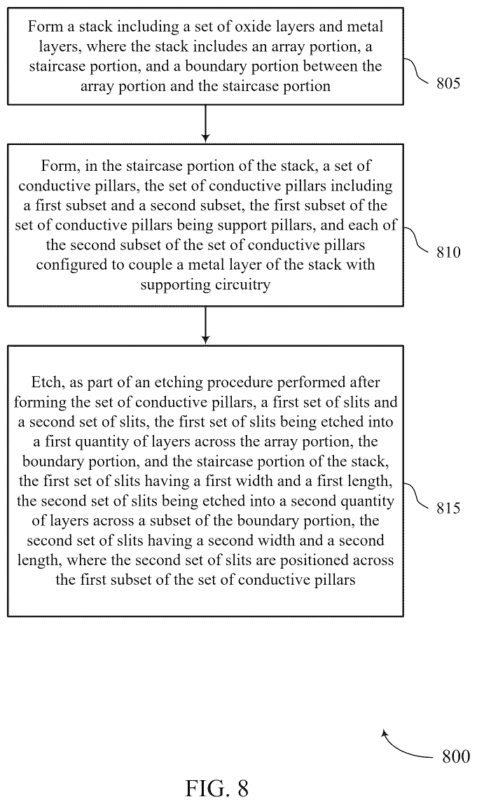

FIG. 8 shows a flowchart illustrating a method 800 that supports mitigating deformities in memory arrays in accordance with examples as disclosed herein. The operations of method 800 may be implemented by a manufacturing system or its components as described herein. In some examples, a manufacturing system may execute a set of instructions to control the functional elements of the device to perform the described functions. Additionally, or alternatively, the manufacturing system may perform aspects of the described functions using special-purpose hardware.

At 805, the method may include forming a stack including a set of oxide layers and metal layers, where the stack includes an array portion, a staircase portion, and a boundary portion between the array portion and the staircase portion.

At 810, the method may include forming, in the staircase portion of the stack, a set of conductive pillars, the set of conductive pillars including a first subset and a second subset, the first subset of the set of conductive pillars being support pillars, and each of the second subset of the set of conductive pillars configured to couple a metal layer of the stack with supporting circuitry.

At 815, the method may include etching, as part of an etching procedure performed after forming the set of conductive pillars, a first set of slits and a second set of slits, the first set of slits being etched into a first quantity of layers across the array portion, the boundary portion, and the staircase portion of the stack, the first set of slits having a first width and a first length, the second set of slits being etched into a second quantity of layers across a subset of the boundary portion, the second set of slits having a second width and a second length, where the second set of slits are positioned across the first subset of the set of conductive pillars.

In some examples, an apparatus as described herein may perform a method or methods, such as the method 800. The apparatus may include features, circuitry, logic, means, or instructions (e.g., a non-transitory computer-readable medium storing instructions executable by a processor), or any combination thereof for performing the following aspects of the present disclosure:

Aspect 1: A method or apparatus including operations, features, circuitry, logic, means, or instructions, or any combination thereof for forming a stack including a set of oxide layers and metal layers, where the stack includes an array portion, a staircase portion, and a boundary portion between the array portion and the staircase portion; forming, in the staircase portion of the stack, a set of conductive pillars, the set of conductive pillars including a first subset and a second subset, the first subset of the set of conductive pillars being support pillars, and each of the second subset of the set of conductive pillars configured to couple a metal layer of the stack with supporting circuitry; and etching, as part of an etching procedure performed after forming the set of conductive pillars, a first set of slits and a second set of slits, the first set of slits being etched into a first quantity of layers across the array portion, the boundary portion, and the staircase portion of the stack, the first set of slits having a first width and a first length, the second set of slits being etched into a second quantity of layers across a subset of the boundary portion, the second set of slits having a second width and a second length, where the second set of slits are positioned across the first subset of the set of conductive pillars.

Aspect 2: The method or apparatus of aspect 1, further including operations, features, circuitry, logic, means, or instructions, or any combination thereof for identifying, prior to performing the etching procedure, the first length of the first set of slits, the first width of the first set of slits, and the first quantity of layers, where etching the first set of slits is in accordance with identifying the first length, the first width, and the first quantity of layers and identifying, prior to performing the etching procedure, the second length of the second set of slits, the second width of the second set of slits, and the second quantity of layers, where etching the second set of slits is in accordance with identifying the second length, the second width, and the second quantity of layers.

Aspect 3: The method or apparatus of aspects 1 through 2, where the first length is greater than the second length.

Aspect 4: The method or apparatus of aspects 1 through 3, where the second width is greater than the first width, the first width is greater than the second width, or the first width is equal to the second width.

Aspect 5: The method or apparatus of aspects 1 through 4, where the second quantity of layers is greater than the first quantity of layers, the first quantity of layers is greater than the second quantity of layers, or the first quantity of layers is equal to the second quantity of layers.

Aspect 6: The method or apparatus of aspects 1 through 5, further including operations, features, circuitry, logic, means, or instructions, or any combination thereof for identifying, prior to performing the etching procedure, a starting point of the second set of slits within the boundary portion, where etching the second set of slits into the subset of the boundary portion is in accordance with identifying the starting point.

Aspect 7: The method or apparatus of aspects 1 through 6, further including operations, features, circuitry, logic, means, or instructions, or any combination thereof for depositing, after the etching procedure, an insulating material into the first set of slits and the second set of slits.

Aspect 8: The method or apparatus of 1 through 7, where forming the stack includes operations, features, circuitry, logic, means, or instructions, or any combination thereof for performing a metallization process to remove a set of nitride layers from the stack to form a set of cavities and deposit a metal in each cavity of the set of cavities to form the set of metal layers, the set of metal layers forming a set of word lines.

Aspect 9: The method or apparatus of aspects 1 through 8, where forming the set of conductive pillars includes operations, features, circuitry, logic, means, or instructions, or any combination thereof for forming, at the staircase portion of the stack, a set of cavities, where each cavity of the set of cavities is associated with a respective layer of the set of oxide layers and nitride layers and depositing a conductive material in each cavity of the set of cavities to form each conductive pillar of the set of conductive pillars.

Aspect 10: The method or apparatus of aspects 1 through 9, further including operations, features, circuitry, logic, means, or instructions, or any combination thereof for forming, at the array portion of the stack, a set of memory cells at each layer of the set of oxide layers and nitride layers, the set of memory cells on each layer forming a memory block, where the first set of slits at the array portion of the stack divide the set of memory cells into a set of memory subblocks.

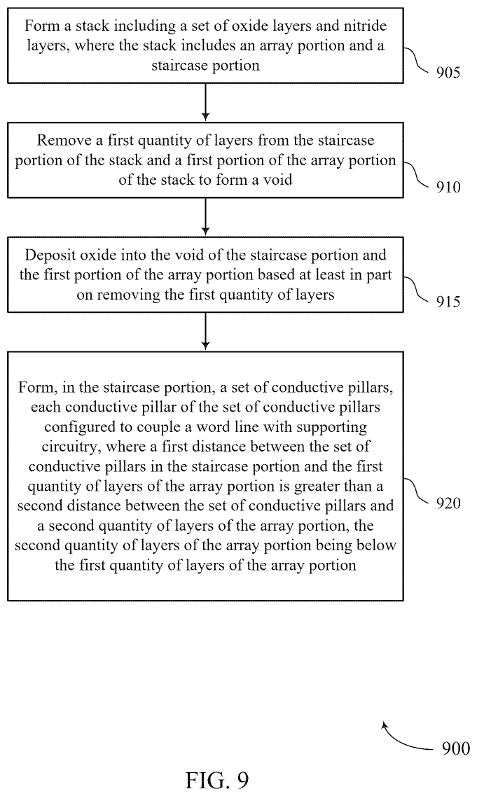

FIG. 9 shows a flowchart illustrating a method 900 that supports mitigating deformities in memory arrays in accordance with examples as disclosed herein. The operations of method 900 may be implemented by a manufacturing system or its components as described herein. In some examples, a manufacturing system may execute a set of instructions to control the functional elements of the device to perform the described functions. Additionally, or alternatively, the manufacturing system may perform aspects of the described functions using special-purpose hardware.

At 905, the method may include forming a stack including a set of oxide layers and nitride layers, where the stack includes an array portion and a staircase portion.

At 910, the method may include removing a first quantity of layers from the staircase portion of the stack and a first portion of the array portion of the stack to form a void.

At 915, the method may include depositing oxide into the void of the staircase portion and the first portion of the array portion based at least in part on removing the first quantity of layers.

At 920, the method may include forming, in the staircase portion, a set of conductive pillars, each conductive pillar of the set of conductive pillars configured to couple a word line with supporting circuitry, where a first distance between the set of conductive pillars in the staircase portion and the first quantity of layers of the array portion is greater than a second distance between the set of conductive pillars and a second quantity of layers of the array portion, the second quantity of layers of the array portion being below the first quantity of layers of the array portion.

In some examples, an apparatus (e.g., a manufacturing system) as described herein may perform a method or methods, such as the method 900. The apparatus may include features, circuitry, logic, means, or instructions (e.g., a non-transitory computer-readable medium storing instructions executable by a processor), or any combination thereof for performing the following aspects of the present disclosure:

Aspect 11: A method or apparatus including operations, features, circuitry, logic, means, or instructions, or any combination thereof for forming a stack including a set of oxide layers and nitride layers, where the stack includes an array portion and a staircase portion; removing a first quantity of layers from the staircase portion of the stack and a first portion of the array portion of the stack to form a void; depositing oxide into the void of the staircase portion and the first portion of the array portion based at least in part on removing the first quantity of layers; and forming, in the staircase portion, a set of conductive pillars, each conductive pillar of the set of conductive pillars configured to couple a word line with supporting circuitry, where a first distance between the set of conductive pillars in the staircase portion and the first quantity of layers of the array portion is greater than a second distance between the set of conductive pillars and a second quantity of layers of the array portion, the second quantity of layers of the array portion being below the first quantity of layers of the array portion.

Aspect 12: The method or apparatus of aspect 11, further including operations, features, circuitry, logic, means, or instructions, or any combination thereof for depositing a first resistive layer over the top layer of a second portion of the array portion of the stack and removing the top layer from the staircase portion and the first portion of the array portion is based at least in part on depositing the first resistive layer, where removing the first quantity of layers is based at least in part on removing the top layer from the staircase portion and the first portion of the array portion.

Aspect 13: The method or apparatus of aspect 12, further including operations, features, circuitry, logic, means, or instructions, or any combination thereof for determining a length of the first resistive layer, where the first distance is based at least in part on the length of the first resistive layer.

Aspect 14: The method or apparatus of aspects 12 through 13, further including operations, features, circuitry, logic, means, or instructions, or any combination thereof for removing the first resistive layer based at least in part on removing the top layer from the staircase portion of the stack and the first portion of the array portion of the stack.

Aspect 15: The method or apparatus of aspects 12 through 14, further including operations, features, circuitry, logic, means, or instructions, or any combination thereof for depositing a second resistive layer over the top layer of a third portion of the array portion of the stack, where removing the first quantity of layers is based at least in part on depositing the second resistive layer.

Aspect 16: The method or apparatus of aspects 15, further including operations, features, circuitry, logic, means, or instructions, or any combination thereof for removing the second resistive layer based at least in part on removing the first quantity of layers.

Aspect 17: The method or apparatus of aspects 12 through 16, further including

operations, features, circuitry, logic, means, or instructions, or any combination thereof for removing the top layer of the second portion of the array portion of the stack based at least in part on depositing the oxide into the void.

Aspect 18: The method or apparatus of aspects 12 through 17, where the top layer

of the stack includes a first oxide layer, a second oxide layer, an intermediate layer between the first oxide layer and the second oxide layer, and a liner below the second oxide layer.

Aspect 19: The method or apparatus of aspects 11 through 18, further including operations, features, circuitry, logic, means, or instructions, or any combination thereof for depositing an oxide liner into the void and depositing a nitride liner on the oxide liner, where depositing the oxide into the void is based at least in part on depositing the nitride liner.

Aspect 20: The method or apparatus of aspects 11 through 19, further including operations, features, circuitry, logic, means, or instructions, or any combination thereof for performing a metallization process to remove each nitride layer from the stack to form a set of cavities and deposit a metal in each cavity of the set of cavities to form a set of word lines.

Aspect 21: The method or apparatus of aspects 11 through 20, further including operations, features, circuitry, logic, means, or instructions, or any combination thereof for forming, at the array portion of the stack, a set of memory cells at each layer of the set of oxide layers and nitride layers, the set of memory cells on each layer forming a block of memory cells.

Aspect 22: The method or apparatus of aspects 11 through 21, where forming the set of conductive pillars further includes operations, features, circuitry, logic, means, or instructions, or any combination thereof for forming, at the staircase portion of the stack, a set of cavities and depositing, in each cavity of the set of cavities, a conductive material to form the set of conductive pillars.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 23: An apparatus, including: a stack of materials including an array portion and a staircase portion, the array portion including: a set of memory subblocks separated by a first set of insulating walls, each insulating wall of the first set of insulating walls having a first width, a first length, and a first depth; and the staircase portion including: a set of conductive pillars including a first subset and a second subset, the first subset of the set of conductive pillars being support pillars, and each of the second subset of the set of conductive pillars coupling a word line with supporting circuitry; the first set of insulating walls; and a second set of insulating walls spanning the first subset of the set of conductive pillars, where each insulating wall of the second set of insulating walls has a second width, a second length, and a second depth.

Aspect 24: The apparatus of aspect 23, where the first length is greater than the second length.

Aspect 25: The apparatus of aspects 23 through 24, wherein the second width is greater than the first width, the first width is greater than the second width, or the first width is equal to the second width.

Aspect 26: The apparatus of aspects 23 through 25, wherein the second depth is greater than the first depth, the first depth is greater than the second depth, or the first depth is equal to the second depth.

Aspect 27: The apparatus of aspects 23 through 26, wherein each of the set of memory subblocks comprise a plurality of memory cells.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a stack of materials comprising an array portion and a staircase portion, the array portion comprising:
a set of memory subblocks separated by a first set of insulating walls, each insulating wall of the first set of insulating walls having a first width, a first length, and a first depth; and
the staircase portion comprising:
a set of conductive pillars comprising a first subset and a second subset, the first subset of the set of conductive pillars being support pillars, and each of the second subset of the set of conductive pillars coupling a word line with supporting circuitry;
the first set of insulating walls; and
a second set of insulating walls spanning the first subset of the set of conductive pillars, wherein each insulating wall of the second set of insulating walls has a second width, a second length, and a second depth.

2. The apparatus of claim 1, wherein the first length is greater than the second length.

3. The apparatus of claim 1, wherein the second width is greater than the first width, the first width is greater than the second width, or the first width is equal to the second width.

4. The apparatus of claim 1, wherein the second depth is greater than the first depth, the first depth is greater than the second depth, or the first depth is equal to the second depth.

5. The apparatus of claim 1, wherein each of the set of memory subblocks comprise a plurality of memory cells.

6. A method, comprising:
forming a stack comprising a set of oxide layers and metal layers, wherein the stack comprises an array portion, a staircase portion, and a boundary portion between the array portion and the staircase portion;
forming, in the staircase portion of the stack, a set of conductive pillars, the set of conductive pillars comprising a first subset and a second subset, the first subset of the set of conductive pillars being support pillars, and each of the second subset of the set of conductive pillars configured to couple a metal layer of the stack with supporting circuitry; and
etching, as part of an etching procedure performed after forming the set of conductive pillars, a first set of slits and a second set of slits, the first set of slits being etched into a first quantity of layers across the array portion, the boundary portion, and the staircase portion of the stack, the first set of slits having a first width and a first length, the second set of slits being etched into a second quantity of layers across a subset of the boundary portion, the second set of slits having a second width and a second length, wherein the second set of slits are positioned across the first subset of the set of conductive pillars.

7. The method of claim 6, further comprising:
identifying, prior to performing the etching procedure, the first length of the first set of slits, the first width of the first set of slits, and the first quantity of layers, wherein etching the first set of slits is in accordance with identifying the first length, the first width, and the first quantity of layers; and
identifying, prior to performing the etching procedure, the second length of the second set of slits, the second width of the second set of slits, and the second quantity of layers, wherein etching the second set of slits is in accordance with identifying the second length, the second width, and the second quantity of layers.

8. The method of claim 6, wherein the first length is greater than the second length.

9. The method of claim 6, wherein the second width is greater than the first width, the first width is greater than the second width, or the first width is equal to the second width.

10. The method of claim 6, wherein the second quantity of layers is greater than the first quantity of layers, the first quantity of layers is greater than the second quantity of layers, or the first quantity of layers is equal to the second quantity of layers.

11. The method of claim 6, further comprising:
identifying, prior to performing the etching procedure, a starting point of the second set of slits within the boundary portion, wherein etching the second set of slits into the subset of the boundary portion is in accordance with identifying the starting point.

12. The method of claim 6, further comprising:
depositing, after the etching procedure, an insulating material into the first set of slits and the second set of slits.

13. The method of claim 6, wherein forming the stack comprises:
performing a metallization process to remove a set of nitride layers from the stack to form a set of cavities and deposit a metal in each cavity of the set of cavities to form a set of metal layers, the set of metal layers forming a set of word lines.

14. The method of claim 6, wherein forming the set of conductive pillars comprises:
forming, at the staircase portion of the stack, a set of cavities, wherein each cavity of the set of cavities is associated with a respective layer of the set of oxide layers and nitride layers; and
depositing a conductive material in each cavity of the set of cavities to form each conductive pillar of the set of conductive pillars.

15. The method of claim 6, further comprising:
forming, at the array portion of the stack, a set of memory cells at each layer of the set of oxide layers and nitride layers, the set of memory cells on each layer forming a memory block, wherein the first set of slits at the array portion of the stack divide the set of memory cells into a set of memory subblocks.

16. A method, comprising:
forming a stack comprising a set of oxide layers and nitride layers, wherein the stack comprises an array portion and a staircase portion;
removing a first quantity of layers from the staircase portion of the stack and a first portion of the array portion of the stack to form a void;
depositing oxide into the void of the staircase portion and the first portion of the array portion based at least in part on removing the first quantity of layers; and
forming, in the staircase portion, a set of conductive pillars, each conductive pillar of the set of conductive pillars configured to couple a word line with supporting circuitry, wherein a first distance between the set of conductive pillars in the staircase portion and the first quantity of layers of the array portion is greater than a second distance between the set of conductive pillars and a second quantity of layers of the array portion, the second quantity of layers of the array portion being below the first quantity of layers of the array portion.

17. The method of claim 16, wherein the stack further comprises a top layer over the set of oxide layers and nitride layers, the method further comprising:
depositing a first resistive layer over the top layer of a second portion of the array portion of the stack; and
removing the top layer from the staircase portion and the first portion of the array portion is based at least in part on depositing the first resistive layer, wherein removing the first quantity of layers is based at least in part on removing the top layer from the staircase portion and the first portion of the array portion.

18. The method of claim 17, further comprising:
determining a length of the first resistive layer, wherein the first distance is based at least in part on the length of the first resistive layer.

19. The method of claim 17, further comprising:
removing the first resistive layer based at least in part on removing the top layer from the staircase portion of the stack and the first portion of the array portion of the stack.

20. The method of claim 17, further comprising:
depositing a second resistive layer over the top layer of a third portion of the array portion of the stack, wherein removing the first quantity of layers is based at least in part on depositing the second resistive layer.
